(19) United States
(12) Patent Application Publication
(10) Pub. No.: US 2025/0338385 A1
(43) Pub. Date: Oct. 30, 2025

(54) WIRING CIRCUIT BOARD

(71) Applicant: NITTO DENKO CORPORATION, Osaka (JP)

(72) Inventors: Takaya KOUCHI, Osaka (JP); Shusaku SHIBATA, Osaka (JP)

(73) Assignee: NITTO DENKO CORPORATION, Osaka (JP)

(21) Appl. No.: 19/187,597

(22) Filed: Apr. 23, 2025

(30) Foreign Application Priority Data
Apr. 25, 2024 (JP) 2024-071979

(51) Int. Cl. H05K 1/02; H05K 1/11

(52) U.S. Cl. CPC H05K 1/0201; H05K 1/111; H05K 2201/09381

(57) ABSTRACT

A wiring circuit board includes a metal layer, a first insulating layer, and a circuit pattern. The circuit pattern includes a terminal and a wire connected to the terminal. The first insulating layer includes a main body portion disposed between the wire and the metal layer, and a heat dissipating portion in contact with the terminal and in contact with the metal layer. The thickness (second thickness) of the heat dissipating portion is smaller than the thickness (first thickness) of the main body portion.

### CROSS-REFERENCE TO RELATED APPLICATION

The present application claims priority from Japanese Patent Application No. 2024-71979 filed on Apr. 25, 2024, the content of which is hereby incorporated by reference into this application.

### TECHNICAL FIELD

The present invention relates to a wiring circuit board.

### BACKGROUND ART

Conventionally, there has been a known wiring circuit board including a metal support layer, a circuit including a pad portion, and a base insulating layer disposed between the metal support layer and the pad portion (for example, see Patent Document 1 below).

### CITATION LIST

### Patent Document

Patent Document 1: Japanese Unexamined Patent Publication No. 2019-212679

### SUMMARY OF THE INVENTION

### Problem to be Solved by the Invention

In the wiring circuit board as described in Patent Document 1, when molten solder is mounted on the pad portion, the heat of the solder is transmitted to the base insulating layer through the pad portion, and the base insulating layer may be damaged.

When the damage to the base insulating layer is excessively increased, the base insulating layer may be easily released from the metal support layer.

The present invention provides a wiring circuit board capable of suppressing damage to the first insulating layer due to the heat transmitted from a terminal to the first insulating layer.

### Means for Solving the Problem

The present invention [1] includes a wiring circuit board including: a metal layer; a circuit pattern having a terminal and a wire connected to the terminal; and a first insulating layer disposed between the metal layer and the circuit pattern in a thickness direction of the metal layer, wherein the first insulating layer includes: a main body portion disposed between the wire and the metal layer and having a first thickness, and a heat dissipating portion having a second thickness smaller than the first thickness, the heat dissipating portion being in contact with the terminal and in contact with the metal layer.

According to such a configuration, the heat dissipating portion in contact with the terminal and in contact with the metal layer is thinner than the main body portion disposed between the wire and the metal layer.

Therefore, when molten solder is mounted on the terminal, the heat transmitted to the heat dissipating portion through the terminal can smoothly be dissipated into the metal layer.

As a result, it is possible to suppress the damage to the first insulating layer due to the heat transmitted from the terminal to the first insulating layer.

The present invention [2] includes the wiring circuit board described in the above-described [1], wherein the circuit pattern includes a plurality of the terminals, and wherein the heat dissipating portion is in contact with the plurality of the terminals.

According to such a configuration, the heat of the plurality of the terminals is concentrated in the heat dissipating portion.

In this regard, the thickness of the heat dissipating portion is smaller than the thickness of the main body portion. Therefore, even when the heat of the plurality of terminals is concentrated in the heat dissipating portion, the heat transmitted to the heat dissipating portion can smoothly be dissipated into the metal layer.

As a result, even when the heat of the plurality of terminals is concentrated in the heat dissipating portion, damage to the first insulating layer can be suppressed.

The present invention [3] includes the wiring circuit board described in the above-described [1], wherein the heat dissipating portion is in contact with the terminal.

According to such a configuration, it is possible to suppress the concentration of the heat of the plurality of the terminals in the heat dissipating portion.

Therefore, damage to the first insulating layer can be further suppressed.

The present invention [4] includes the wiring circuit board described in any one of the above-described [1] to [3], wherein the heat dissipating portion is in contact with a whole of the terminal.

The present invention [5] includes the wiring circuit board described in any one of the above-described [1] to [3], wherein the heat dissipating portion is in contact with a portion of the terminal.

The present invention [6] includes the wiring circuit board described in the above-described [5], wherein the portion of the terminal is a peripheral edge portion of the terminal.

The present invention [7] includes the wiring circuit board described in the above-described [5], wherein the portion of the terminal is a central portion of the terminal.

The present invention [8] includes the wiring circuit board described in any one of the above-described [1] to [7], further including: a second insulating layer disposed on the first insulating layer and covering the wire, wherein the terminal protrudes toward an opposite side to the metal layer with respect to the first insulating layer as compared with the second insulating layer.

According to such a configuration, the thickness of the terminal can be ensured.

Therefore, when solder melts on the terminal, it is possible to suppress the transmission of the heat of the solder to the second insulating layer.

The present invention [9] includes the wiring circuit board described in any one of the above-described [1] to [7], wherein the terminal includes: a first conductor layer disposed on the first insulating layer, and a second conductor layer disposed on the first conductor layer.

According to such a configuration, the terminal can thickly be formed from the first conductor layer and the second conductor layer.

As a result, when solder melts on the terminal, it is possible to suppress the transmission of the heat of the solder to the second insulating layer.

### Effects of the Invention

According to the wiring circuit board of the present invention, it is possible to suppress damage to the first insulating layer due to the heat transmitted from the terminal to the first insulating layer.

### BRIEF DESCRIPTION OF THE DRAWINGS

FIG. 1 is a plan view of a wiring circuit board as one embodiment of the present invention.

FIG. 2 is a cross-sectional view of the wiring circuit board shown in FIG. 1, taken along line A-A.

FIGS. 3A to 3D show steps of producing the wiring circuit board shown in FIG. 2, FIG. 3A shows a first insulating layer forming step, FIG. 3B shows a first conductor layer forming step, FIG. 3C shows a second conductor layer forming step, and FIG. 3D shows a second insulating layer forming step.

FIG. 4 is a cross-sectional view of a wiring circuit board of a modified example (1).

FIG. 5 is a cross-sectional view of a wiring circuit board of a modified example (2).

FIG. 6A to FIG. 6C show a wiring circuit board of a modified example (3), FIG. 6A shows a plan view of the wiring circuit board of the modified example (3), FIG. 6B shows a cross-sectional view of the wiring circuit board shown in FIG. 6A, taken along line B-B, and FIG. 6C shows a cross-sectional view of the wiring circuit board shown in FIG. 6A, taken along line C-C.

FIGS. 7A to 7C show a wiring circuit board of a modified example (4), FIG. 7A shows a plan view of the wiring circuit board of the modified example (4), FIG. 7B shows a cross-sectional view of the wiring circuit board shown in FIG. 7A, taken along line D-D, and FIG. 7C shows a cross-sectional view of the wiring circuit board shown in FIG. 7A, taken along line E-E.

FIGS. 8A to 8C show a wiring circuit board of a modified example (5), FIG. 8A shows a plan view of the wiring circuit board of the modified example (5), FIG. 8B shows a cross-sectional view of the wiring circuit board shown in FIG. 8A, taken along line F-F, and FIG. 8C shows a cross-sectional view of the wiring circuit board shown in FIG. 8A, taken along line G-G.

FIGS. 9A to 9C show a wiring circuit board of a modified example (6), FIG. 9A shows a plan view of the wiring circuit board of the modified example (6), FIG. 9B shows a cross-sectional view of the wiring circuit board shown in FIG. 9A, taken along line H-H, and FIG. 9C shows a cross-sectional view of the wiring circuit board shown in FIG. 9A, taken along line I-1.

### DESCRIPTION OF THE EMBODIMENT

### 1. Wiring Circuit Board

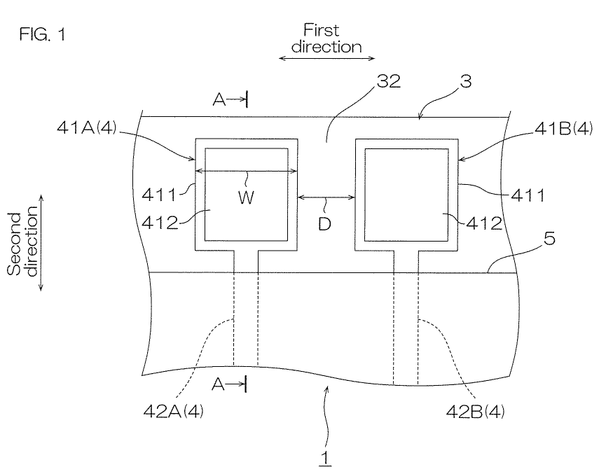

As shown in FIG. 1, a wiring circuit board 1 extends in a first direction and a second direction. The second direction is perpendicular to the first direction. The shape of the wiring circuit board 1 is not limited. The wiring circuit board 1 may be a flexible wiring circuit board or a suspension board with circuit.

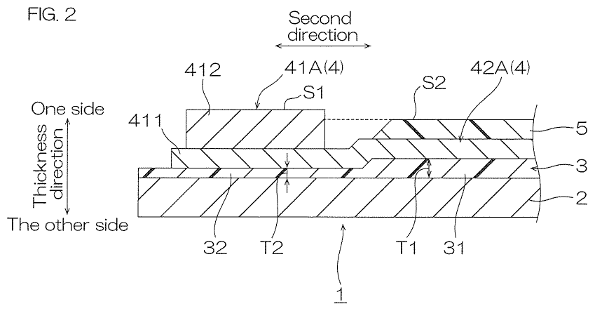

As shown in FIG. 2, the wiring circuit board 1 includes a metal layer 2, a first insulating layer 3, a circuit pattern 4, and a second insulating layer 5.

### (1) Metal Layer

A metal layer 2 supports the first insulating layer 3, the circuit pattern 4, and the second insulating layer 5. Examples of the material of the metal layer 2 include stainless steel and a copper alloy. The metal layer 2 may have a plurality of layers made of different metals.

### (2) First Insulating Layer

The first insulating layer 3 is disposed at one side of the metal layer 2 in a thickness direction of the metal layer 2. The thickness direction is perpendicular to the first direction and the second direction. The first insulating layer 3 is disposed on a one-side surface of the metal layer 2 in the thickness direction. The first insulating layer 3 is disposed between the metal layer 2 and the circuit pattern 4 in the thickness direction. The first insulating layer 3 is capable of insulating the metal layer 2 from the circuit pattern 4. The first insulating layer 3 is made of resin. Examples of the resin include polyimide, maleimide, epoxy resin, polybenzoxazole, and polyester. The first insulating layer 3 includes a main body portion 31 and a heat dissipating portion 32.

The main body portion 31 is disposed between a wire 42A of the circuit pattern 4 and the metal layer 2. The wire 42A is described later. The main body portion 31 is capable of insulating the metal layer 2 from the wire 42A. The main body portion 31 has a first thickness T1. The first thickness T1 is, for example, 5 μm to 30 μm.

The heat dissipating portion 32 is disposed between at least a portion of the terminal 41A of the circuit pattern 4 and the metal layer 2. The terminal 41A is described later. In the present embodiment, the heat dissipating portion 32 is disposed between the whole of the terminal 41A and the metal layers 2 in the thickness direction. The heat dissipating portion 32 is capable of insulating the metal layer 2 from the terminal 41A, and when solder melts on the terminal 41A, the heat transmitted to the heat dissipating portion 32 through the terminal 41A can smoothly be dissipated into the metal layer 2. The heat dissipating portion 32 has a second thickness T2. The second thickness T2 is thinner than the first thickness T1. The second thickness T2 is, for example, 1 μm to 25 μm. The heat dissipating portion 32 is in contact with the whole of the terminal 41A and in contact with the metal layers 2. Specifically, as shown in FIG. 1, the heat dissipating portion 32 extends in the first direction and the second direction. The heat dissipating portion 32 is in contact with the whole of the terminal 41A in the first direction and is in contact with the whole of the terminal 41A in the second direction.

The heat dissipating portion 32 is in contact with a plurality of terminals 41A and 41B. Therefore, the heat of the terminals 41A and 41B is concentrated in the heat dissipating portion 32. In this regard, the thickness (second thickness T2) of the heat dissipating portion 32 is smaller than the thickness (first thickness T1) of the main body portion 31. Therefore, even when the heat of the terminals 41A and 41B is concentrated in the heat dissipating portion 32, the heat transmitted to the heat dissipating portion 32 can smoothly be dissipated into the metal layer 2.

### (3) Circuit Pattern

As shown in FIG. 2, the circuit pattern 4 is disposed at one side of the first insulating layer 3 in the thickness direction. The circuit pattern 4 is disposed on a one-side surface of the first insulating layer 3 in the thickness direction. The circuit pattern 4 is disposed on an opposite side to the metal layer 2 with respect to the first insulating layer 3 in the thickness direction.

As shown in FIG. 1, the circuit pattern 4 includes a plurality of terminals 41A and 41B and a plurality of wires 42A and 42B.

At least a portion of the terminal 41A is disposed on the heat dissipating portion 32 of the first insulating layer 3. In the present embodiment, the whole of the terminal 41A is disposed on the heat dissipating portion 32. As illustrated in FIG. 2, the terminal 41A includes a first conductor layer 411 and a second conductor layer 412.

The first conductor layer 411 is disposed on the first insulating layer 3 in the thickness direction. As shown in FIG. 1, the first conductor layer 411 extends in the first direction and the second direction. The first conductor layer 411 has a square land shape. The first conductor layer 411 is made of metal. Examples of the metal include, for example, copper, silver, gold, iron, aluminum, chromium, and the alloys thereof. From the viewpoint of obtaining good electrical properties, the first conductor layer 411 is preferably made of copper.

As shown in FIG. 2, the second conductor layer 412 is disposed on the first conductor layer 411 in the thickness direction. The second conductor layer 412 protrudes toward the opposite side to the metal layer 2 (that is, one side in the thickness direction) with respect to the first insulating layer 3 in the thickness direction as compared with the second insulating layer 5. In other words, the terminal 41A protrudes toward the side opposite to the metal layer 2 with respect to the first insulating layer 3 in the thickness direction as compared with the second insulating layer 5. In this manner, when the thickness of the terminal 41A is ensured, and solder melts on the terminal 41A, it is possible to suppress the transmission of the heat of the solder to the second insulating layers 5. In the thickness direction, a one-side surface S1 of the terminal 41A is disposed at one side as compared with a one-side surface S2 of the second insulating layer 5. As shown in FIG. 1, the second conductor layer 412 extends in the first direction and the second direction. The second conductor layer 412 has a substantially rectangular shape. The second conductor layer 412 is made of the same metal as that of the first conductor layer 411.

The terminal 41B is aligned with the terminal 41A in the first direction. The terminal 41B is disposed away from the terminal 41A in the first direction. At least a portion of the terminal 41A is disposed on the heat dissipating portion 32 of the first insulating layer 3. In the present embodiment, the entire terminal 41A is disposed on the heat dissipating portion 32. The terminal 41B includes a first conductor layer 411 and a second conductor layer 412 in the same manner as the terminal 41A.

A width W (dimension in the first direction) of each of the terminals 41A and 41B is, for example, 10 μm to 1000 μm, preferably 50 μm to 900 μm.

A distance D between the terminal 41A and the terminal 41B in the first direction is, for example, 10 μm to 500 μm, preferably 20 μm to 400 μm.

The wire 42A is disposed on the main body portion 31 (see FIG. 2) of the first insulating layers 3. The wire 42A extends in the second direction. One end portion of the wire 42A in the second direction is connected to the terminal 41A. One end portion of the wire 42A in the second direction may be disposed on the heat dissipating portion 32 of the first insulating layer 3 together with the terminal 41A. Specifically, the wire 42A is connected to the first conductor layer 411 of the terminal 41A. The wire 42A is made of the same metal material as that of the first conductor layer 411 of the terminal 41A. The wire 42A may be curved toward the first direction.

The wire 42B is aligned with the wire 42A in the first direction. The wire 42B is disposed away from the wire 42A in the first direction. The description of the wire 42B is the same as the description of the wire 42A, and thus is omitted.

### (4) Secondary Insulating Layer

The second insulating layer 5 is disposed at one side of the first insulating layer 3 in the thickness direction. The second insulating layer 5 is disposed on the one-side surface of the first insulating layer 3 in the thickness direction. The second insulating layer 5 covers the wires 42A and 42B. The second insulating layer 5 does not cover the terminals 41A and 41B. The second insulating layer 5 is made of resin. Examples of the resin include polyimide, maleimide, epoxy resin, polybenzoxazole, and polyester.

### 2. Method of Producing Wiring Board

Next, a method of producing the wiring circuit board 1 will be described.

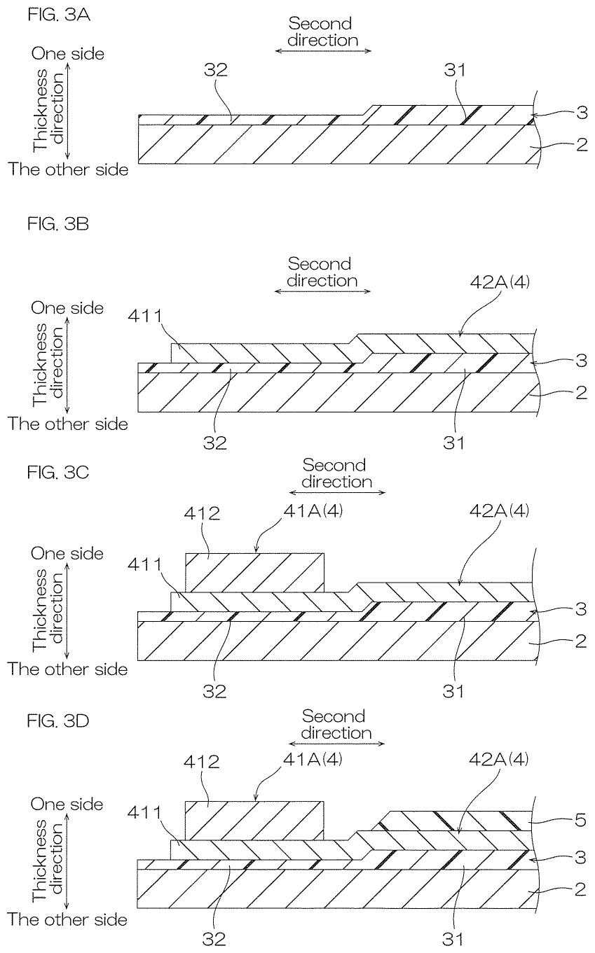

A method of producing the wiring circuit board 1 includes a first insulating layer forming step (see FIG. 3A), a first conductor layer forming step (see FIG. 3B), a second conductor layer forming step (see FIG. 3C), and a second insulating layer forming step (see FIG. 3D).

### (1) First Insulating Layer Forming Step

As shown in FIG. 3A, in the first insulating layer forming step, a first insulating layer 3 is formed on a metal layer 2. In the first insulating layer forming step, a main body portion 31 and a heat dissipating portion 32 are formed in the first insulating layer 3 by the gradation exposure.

Specifically, first, a solution (varnish) of a photosensitive resin is applied onto the metal layer 2 and dried to form a coating film of the photosensitive resin.

Next, the coating film of the photosensitive resin is subjected to gradation exposure using a photomask having a light-shielding portion, a fully-transmissive portion, and a semi-transmissive portion. The light-shielding portion faces a portion of the coating film of the photosensitive resin where a first insulating layer 3 is not formed. The fully transmissive portion faces a portion of the coating film of the photosensitive resin where a main body portion 31 is to be formed. The semi-transmissive portion faces a portion of the coating film of the photosensitive resin where a heat dissipating portion 32 is to be formed.

Next, the exposed coating film is developed. The portion of the coating film that faces the semi-transmissive portion is developed thinner than the portion that faces the fully-transmissive portion. In this manner, the first insulating layer 3 is formed into the above-described pattern on the metal layer 2.

### (2) First Conductor Layer Forming Step

Next, as shown in FIG. 3B, in the first conductor layer forming step, a first conductor layer 411 of terminals 41A and 41B, and wires 42A and 42B are formed on the first insulating layer 3.

Specifically, in the first conductor layer forming step, first, a seed layer is formed on a one-side surface of the first insulating layer 3 and a one-side surface of the metal layer 2 in the thickness direction. The seed layer is formed, for example, by sputtering. Examples of the material of the seed layer include, for example, chromium, copper, nickel, titanium, and the alloys thereof.

Next, a plating resist is attached to the one-side surface of the metal layer 2 in the thickness direction. The plating resist covers the first insulating layer 3.

Next, the plating resist is exposed to light and developed. Then, the plating resist in the portion where a first conductor layer 411 and wires 42A and 42B are to be formed is removed, and the seed layer is exposed in the portion where a first conductor layer 411 and wires 42A and 42B are to be formed. On the other hand, the plated resist in the portion where a first conductor layer 411 and wires 42A and 42B are not formed remains.

Next, a first conductor layer 411 and wires 42A and 42B are formed on the exposed seed layer by electrolytic plating. After the electrolytic plating is completed, the plating resist is released.

### (3) Second Conductor Layer Forming Step

Next, as shown in FIG. 3C, in the second conductor layer forming step, a second conductor layer 412 of terminals 41A and 41B is formed on the first conductor layer 411.

Specifically, in the second conductor layer forming step, a plating resist is attached to the one-side surface of the metal layer 2 in the thickness direction. The plating resist covers the first insulating layer 3, the first conductor layer 411, and the wires 42A and 42B.

Next, the plating resist is exposed to light and developed. Then, the plating resist in the portion where a second conductor layer 412 is to be formed is removed, and the first conductor layer 411 is exposed in the portion where a second conductor layer 412 is to be formed. On the other hand, the plating resist in the portion where a second conductor layer 412 is not formed remains.

Next, a second conductor layer 412 is formed on the exposed first conductor layer 411 by electrolytic plating. After the electrolytic plating is completed, the plating resist is released.

Thereafter, the seed layer exposed by the release of the plating resist is removed by etching.

### (4) Second Insulating Layer Forming Step

Next, as shown in FIG. 3D, in the second insulating layer forming step, a second insulating layer 5 is formed on the first insulating layer 3.

Specifically, in the second insulating layer forming step, first, a solution (varnish) of a photosensitive resin is applied onto the circuit pattern 4, the first insulating layer 3, and the metal layer 2 and dried to form a coating film of the photosensitive resin.

Next, the coating film of the photosensitive resin is exposed to light and developed. In this manner, the second insulating layer 5 is formed into the above-described pattern on the first insulating layer 3.

### 3. Operations and Effects

(1) According to the wiring circuit board 1, as shown in FIG. 2, the heat dissipating portion 32 in contact with the terminal 41A and in contact with the metal layer 2 is thinner than the main body portion 31 disposed between the wire 42A and the metal layer 2.

Therefore, when molten solder is mounted on the terminal 41A, the heat transmitted to the heat dissipating portion 32 through the terminal 41A can smoothly be dissipated into the metal layers 2.

Consequently, damage to the first insulating layer 3 due to the heat transmitted from the terminal 41A to the first insulating layer 3 can be suppressed.

(2) According to the circuit board 1, as shown in FIG. 1, the circuit pattern 4 has a plurality of terminals 41A and 41B. The heat dissipating portion 32 is in contact with the plurality of terminals 41A and 41B.

Therefore, the heat of the plurality of terminals 41A and 41B is concentrated in the heat dissipating portion 32.

In this regard, as shown in FIG. 2, the thickness (second thickness T2) of the heat dissipating portion 32 is smaller than the thickness (first thickness T1) of the main body portion 31. Therefore, even when the heat of the plurality of terminals 41A and 41B is concentrated in the heat dissipating portion 32, the heat transmitted to the heat dissipating portion 32 can smoothly be dissipated into the metal layer 2.

Consequently, even when the heat of the plurality of terminals 41A and 41B is concentrated in the heat dissipating portion 32, damage to the first insulating layer 3 can be suppressed.

(3) According to the wiring circuit board 1, as shown in FIG. 2, the terminal 41A protrudes toward the opposite side to the metal layer 2 with respect to the first insulating layer 3 as compared with the second insulating layer 5.

Therefore, the thickness of the terminal 41A can be ensured.

Consequently, when solder melts on the terminal 41A, it is possible to suppress the transmission of the heat of the solder to the second insulating layer 5.

(4) According to the wiring circuit board 1, as shown in FIG. 2, the terminal 41A includes the first conductor layer 411 and the second conductor layer 412.

Therefore, the terminal 41A can be formed thickly from the first conductor layer 411 and the second conductor layer 412.

Consequently, when solder melts on the terminal 41A, it is possible to suppress the transmission of the heat of the solder to the second insulating layer 5.

### 4. Modified Examples

Modified examples are described. In the modified examples, the same members as the above-described embodiment are given the same numerical references and the descriptions thereof are omitted.

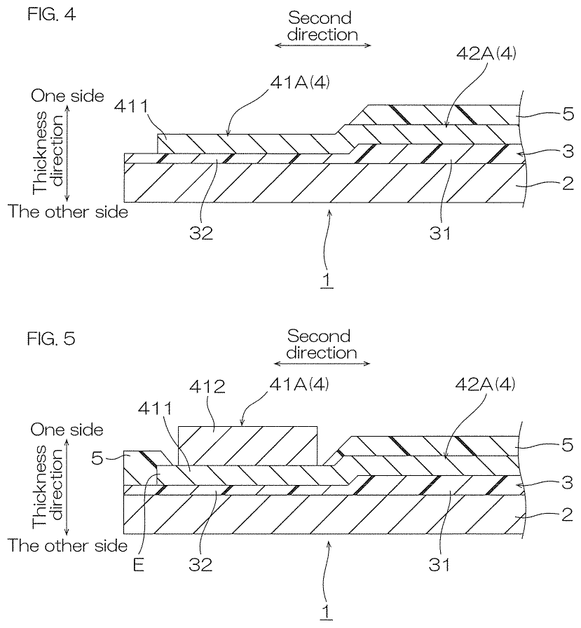

(1) As shown in FIG. 4, the terminal 41A may not include a second conductor layer 412. The terminal 41A may be formed of a first conductor layer 411.

(2) As shown in FIG. 5, the second insulating layer 5 may cover a peripheral edge portion E of the first conductor layer 411 of the terminal 41A. The peripheral edge portion E is one end portion of the first conductor layer 411 in the first direction, the other end portion of the first conductor layer 411 in the first direction, one end portion of the first conductor layer 411 in the second direction, and the other end portion of the first conductor layer 411 in the second direction. That is, the second insulating layer 5 may cover one end portion of the first conductor layer 411 in the first direction, the other end portion of the first conductor layer 411 in the first direction, one end portion of the first conductor layer 411 in the second direction, and the other end portion of the first conductor layer 411 in the second direction. The second insulating layer 5 does not cover the second conductor layer 412 of the terminal 41A.

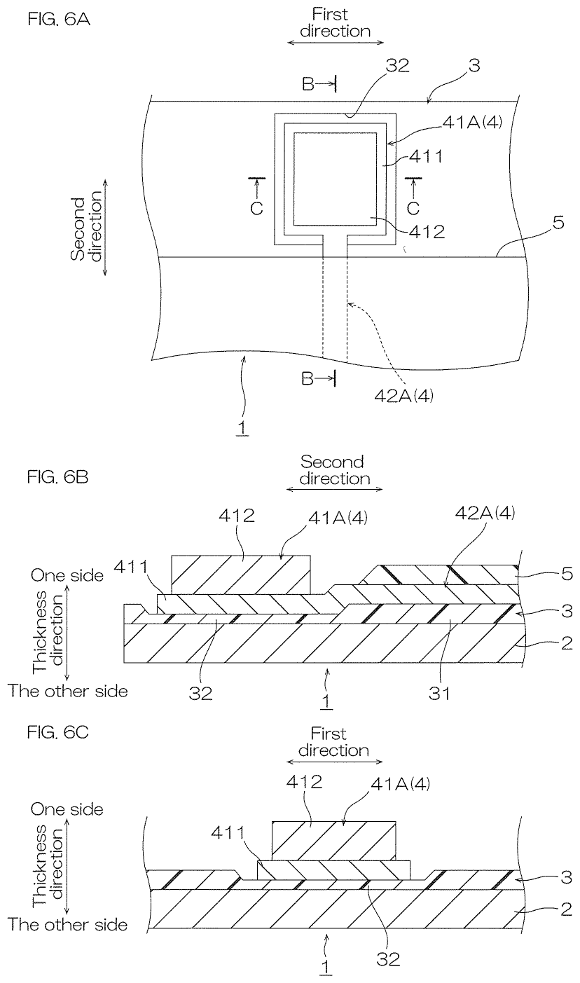

(3) As shown in FIGS. 6A to 6C, the heat dissipation unit 32 may be in contact with one terminal 41A. The heat dissipating portion 32 may be in contact with the whole of one terminal 41A.

In this case, it is possible to suppress the concentration of the heat of the plurality of terminals in the heat dissipating portion 32.

Therefore, damage to the first insulating layer 3 can be further suppressed.

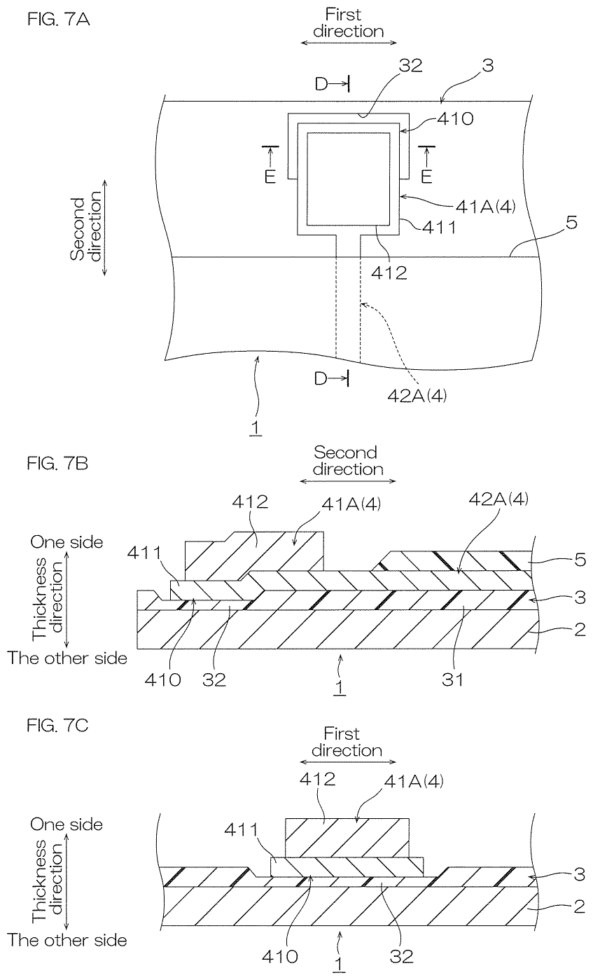

(4) The heat dissipating portion 32 may be in contact with a portion of the terminal 41A. As shown in FIGS. 7A to 7C, a portion of the terminal 41A may be a portion 410 (e.g., a one-side half) of the terminal 41A in the second direction. In this modified example, the heat dissipating portion 32 is not in contact with the other-side half of the terminal 41A in the second direction.

Given that the area of the terminal 41A is 100% in the first direction and the second direction, the area of the portion of the terminal 41A is, for example, 50% or more, preferably 75% or more.

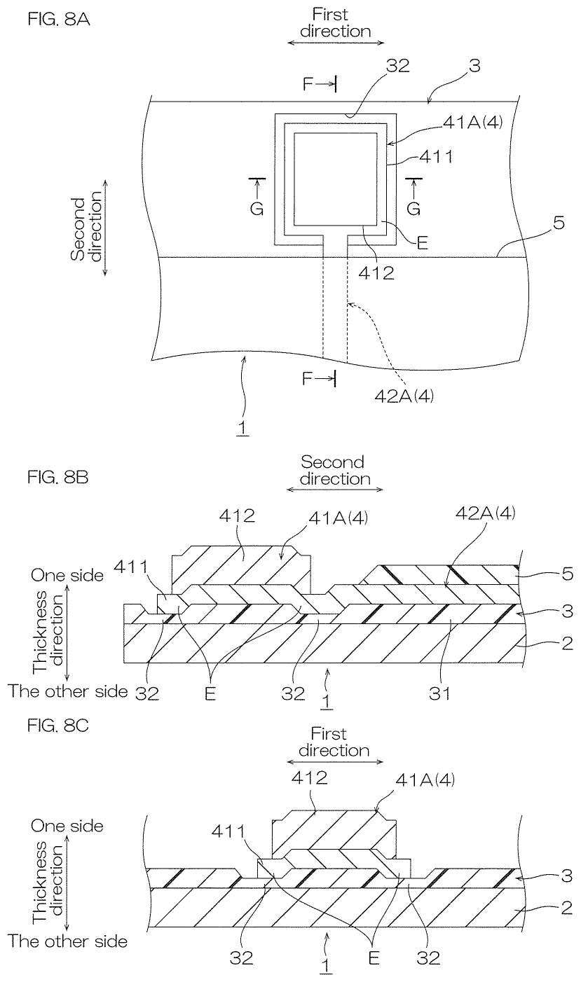

(5) As shown in FIGS. 8A to 8C, the portion of the terminal 41A may be a peripheral edge portion E of the terminal 41A. That is, the heat dissipating portion 32 may be in contact with one end portion of the first conductor layer 411 in the first direction, the other end portion of the first conductor layer 411 in the first direction, one end portion of the first conductor layer 411 in the second direction, and the other end portion of the first conductor layer 411 in the second direction. In this modified example, the heat dissipating portion 32 is not in contact with a central portion of the first conductor layer 411 in the first direction and a central portion of the first conductor layer 411 in the second direction.

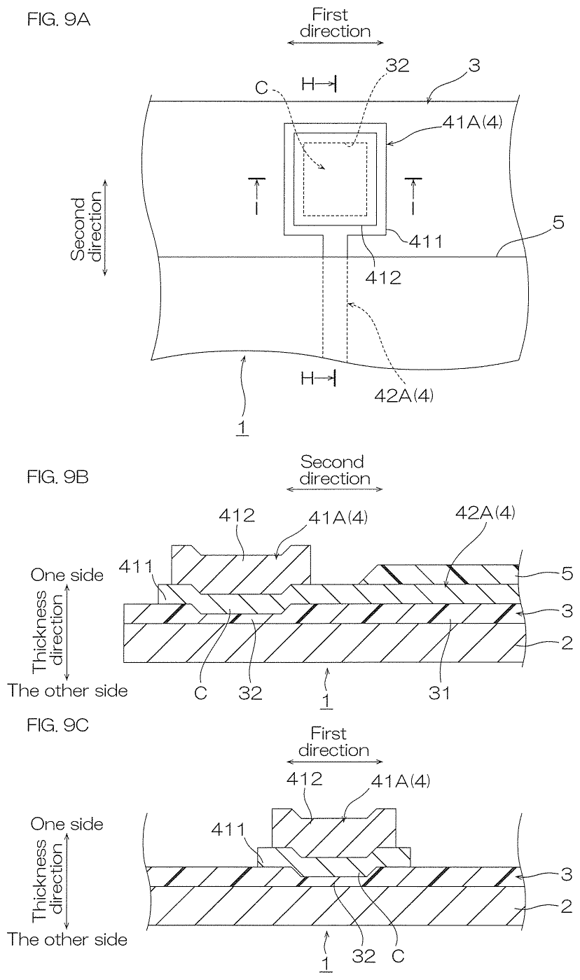

(6) As shown in FIGS. 9A to 9C, the portion of the terminal 41A may be a central portion C of the terminal 41A. The central portion C is the central portion of the first conductor layer 411 in the first direction and the central portion of the first conductor layer 411 in the second direction. That is, the heat dissipating portion 32 may be in contact with the central portion of the first conductor layer 411 in the first direction and the central portion of the first conductor layer 411 in the second direction. In this modified example, the heat dissipating portion 32 is not in contact with one end portion of the first conductor layer 411 in the first direction, the other end portion of the first conductor layer 411 in the first direction, one end portion of the first conductor layer 411 in the second direction, and the other end portion of the first conductor layer 411 in the second direction.

(7) In the modified examples (1) to (6), the same effects as those of the above-described embodiment can be obtained.

(8) The above-described embodiment and modified examples (1) to (6) can be combined.

While the illustrative embodiments of the present invention are provided in the above description, such is for illustrative purpose only and it is not to be construed as limiting the scope of the present invention. modified example and variation of the present invention that will be obvious to those skilled in the art is to be covered by the following claims.

### INDUSTRIAL APPLICABILITY

The wiring circuit board of the present invention can be used for connecting electronic components.

### DESCRIPTION OF REFERENCE NUMERALS

1 Wiring circuit board
2 Metal layer
3 First Insulating Layer
4 Circuit pattern
5 Second Insulating Layer
31 Main body unit
32 Heat dissipating portion
41A Terminal
41B Terminal
42A Wire
42B Wire
410 Portion
411 First conductor layer
412 Second conductor layer
C Central portion
E Peripheral edge portion

1. A wiring circuit board comprising:
a metal layer;
a circuit pattern having a terminal and a wire connected to the terminal; and
a first insulating layer disposed between the metal layer and the circuit pattern in a thickness direction of the metal layer,
wherein the first insulating layer includes:
a main body portion disposed between the wire and the metal layer and having a first thickness, and
a heat dissipating portion having a second thickness smaller than the first thickness, the heat dissipating portion being in contact with the terminal and in contact with the metal layer.

2. The wiring circuit board according to claim 1,
wherein the circuit pattern includes a plurality of the terminals, and
wherein the heat dissipating portion is in contact with the plurality of the terminals.

3. The wiring circuit board according to claim 1,
wherein the heat dissipating portion is in contact with the terminal.

4. The wiring circuit board according to claim 1,
wherein the heat dissipating portion is in contact with a whole of the terminal.

5. The wiring circuit board according to claim 1,
wherein the heat dissipating portion is in contact with a portion of the terminal.

6. The wiring circuit board according to claim 5,
wherein the portion of the terminal is a peripheral edge portion of the terminal.

7. The wiring circuit board according to claim 5,
wherein the portion of the terminal is a central portion of the terminal.

8. The wiring circuit board according to claim 1, further comprising:
a second insulating layer disposed on the first insulating layer and covering the wire, wherein the terminal protrudes toward an opposite side to the metal layer with respect to the first insulating layer as compared with the second insulating layer.

9. The wiring circuit board according to claim 1,
wherein the terminal includes:
a first conductor layer disposed on the first insulating layer, and
a second conductor layer disposed on the first conductor layer.
